(19) United States
(12) Patent Application Publication
(10) Pub. No.: US 2012/0275611 A1
(43) Pub. Date: Nov. 1, 2012

(54) Movement Control Device and Method of Use Thereof

(76) Inventor: Jonathan Shaw, Shipley (GB)

(21) Appl. No.: 13/513,475

(22) PCT Filed: Dec. 1, 2010
(86) PCT No.: PCT/GB2010/051998

§ 371 Date: Jul. 20, 2012

(30) Foreign Application Priority Data
Dec. 3, 2009 (GB) 0921160.8

(51) Int. Cl. H03G 3/20; H03G 5/00

(52) U.S. Cl. 381/57; 381/98

(57) ABSTRACT

A movement control device is provided including audio means for emitting sound audible to a human. At least part of the audible sound includes a repetitive intermittent audible sound provided at such a frequency and/or rate sufficient to allow a person hearing the sound to fall into step with the sound to affect the speed at which the person moves from a first locality to at least a second locality.

This invention relates to a movement control or evacuation device and method of use thereof.

Although the following description refers almost exclusively to an evacuation device for use in the event of fire, it will be appreciated by persons skilled in the art that the present invention can be used for any application where the movement of a crowd or the movement of one or more people between at least a first and second locality is required.

It is well known to provide fire alarms in buildings, such as homes and/or offices which, when activated, inform one or more people located in the buildings that they need to evacuate the building as quickly as possible due to a fire or fire risk. Such fire alarms are typically in the form of a continuous audible sound, although intermittent audible sounds can also be used. The fire alarms are typically activated following manual activation by a user in the building or automatically as a result of detection means detecting smoke, excessive heat and/or the like. Whilst these conventional types of alarm are effective at alerting people within a building to a fire risk, they are not effective at controlling the movement of people from the building. It is often the case that people will not appreciate the risk and will walk slowly, possibly talking to other people around them, thereby delaying their exit and the exit of other people from the building.

It is an aim of the present invention to provide a movement control device or an evacuation device which controls, or at least aids, the movement of one or more people from at least a first locality to a second locality.

It is a further aim of the present invention to provide a method of using an evacuation device or movement control device.

It is a yet further aim of the present invention to provide movement control means and method of use thereof.

According to a first aspect of the present invention there is provided a movement control device, said movement control device including audio means for emitting sound audible to a human, at least part of said audible sound emitted including a repetitive intermittent audible sound, the repetitive intermittent audible sound provided at a pre-determined frequency and/or rate sufficient to allow a person hearing the sound to fall into step with the intermittent sound to affect the speed at which said person moves from a first locality to at least a second locality.

The applicants have found that repetitive intermittent audible sounds played at a particular pre-determined frequency, pitch and/or rate or range of pre-determined frequencies and/or rates can significantly alter the speed at which a person hearing the sound will move between a first locality and at least a second locality. The person hearing the sound is found to consciously or sub-consciously fall into step with the beat or peak of the sound, thereby altering their speed of movement compared to when no repetitive intermittent sound is played or repetitive intermittent sounds at other than the pre-determined frequency and/or rates are played. The advantage of the present invention is that it results in a faster and/or more controlled movement of people between localities.

The present invention has many potential applications where the control of movement of people may be desired, such as for example but not necessarily limited to, for evacuation purposes, such as the evacuation of a sports stadium, music arena, theatre, cinema, building, aeroplane, and/or the like. The application need not be limited to an indoor environment and could equally be used in an outside environment. In addition, the application need not be limited to movement of people to allow evacuation of an area or locality but could be used to control movement of one or more people entering a particular area or locality, such as for example, to encourage theatre goers to find their seats quickly, to encourage school children to get to class and/or the like.

For example, significant costs may be incurred by airlines as a result of any delays during boarding and/or disembarking of passengers from an aircraft. The present invention could be used to speed up the process of boarding and/or disembarking to save costs for the airline and to speed up airport transit time.

The pre-determined frequency and/or range of frequencies at which the device can operate can be dependent on one or more factors, such as for example, the environment or locality in which the device is being used, the one or more people who the device is to be used on, the desired speed or range of speed at which the device is designed to control. For example, people of different ages have different ranges of hearing. As people get older, the range of frequencies over which people can hear sound decreases. Thus, if the device is to be used in an old peoples home for example, the pre-determined frequency may need to be different from the frequency used if the device is to be used in a school of young people. Likewise, the rate at which an audible sound and/or audible beat is played may need to be adjusted depending on the mobility and/or potential speed of the people hearing the audio sound and/or beat to move at the rate of said audio sound and/or beat.

Thus, in one embodiment the device has adjustment means to allow the device to operate at one or more different frequencies, volumes and/or rates to produce repetitive intermittent audible sounds at said different frequencies, volumes and/or rates. One of a plurality of different pre-determined frequencies and/or rates can be selected by a user, device fitter, manufacturer and/or the like using said adjustment means.

In one embodiment the adjustment means allows a user to arbitrary select a particular audio frequency, volume and/or rate within a pre-determined audio range of frequency, volume and/or rate.

The adjustment means can be operated remotely and/or can be operated by any or any combination of a button, switch, key, lever, keyboard, digital display, dial and/or the like associated with the device.

In one embodiment the frequency of the repetitive intermittent audio sound is within the range of 200 Hz-4 kHz. Further preferably the pre-determined and/or predominant frequency is within the range of 450-550 Hz and yet further preferably the frequency is approximately 500 Hz.

Preferably the repetitive intermittent audio sound is in the form of a drum beat. Further preferably the drum beat is in two time (i.e. with stress or emphasis placed on a first beat of a pair of drum beats).

In one embodiment the pre-determined rate of the repetitive intermittent audio sound is within the range of 40-160 audio beats/minute (bpm). Preferably the pre-determined rate of the intermittent audio is approximately 96 audio beats/minute (bpm).

Preferably the repetitive intermittent audible sound is played at a pre-determined volume. The volume typically depends on an average or measured ambient sound level of the particular locality in which the device is to be used. For example, in one embodiment the volume can be within the range of 70-85 dB or close to ambient sounds levels in the locality of the device. Preferably the volume is approximately 60 dB at a distance of 1 metre from the device.

In one embodiment the device can include volume measurement means to measure the ambient sound in the locality in which the device is located prior to setting and/or adjusting the volume of the sound emitted from the device. Preferably the device has means to adjust the volume of the audible sound emitted therefrom to a level substantially equal to or above the measured background noise level.

Preferably the intermittent audible sound is played repetitively for the duration for which the device is activated or for one or more time periods. Timing means can be provided to allow the device to be activated for one or more pre-determined time periods.

The time period between each individual audible sound forming the repetitive intermittent audible sound (i.e. the period where there is no sound or any sound is outside the normal audible range of a person or the person in question) can be substantially equal in length over the time of activation of the device. This typically provides a music or audio “beat” that a person hearing the noise can easily fall into step with.

Thus, in one embodiment, the repetitive intermittent audio sound is a repetitive audio “beat” at a pre-determined frequency, at an increasing and/or decreasing frequency, at two or more alternating frequencies and/or the like, each beat separated by a time period of no sound, sound that is below or above a certain threshold, sound that is significantly different in frequency to the “beat” and/or the like.

In one embodiment the time period between each individual audible sound forming the repetitive intermittent audible sound is unequal in length, increases or decreases in length over the time of activation of the device.

In one embodiment the repetitive intermittent audible sound forms part of a piece of music played by the device. In this embodiment further audible sounds can be played by the device at the same time as the repetitive intermittent audible sound is played by the device. For example, a repetitive intermittent audible sound could be played in the background of further continuous or intermittent audible sounds. The further continuous or intermittent audible sounds or music could be provided at the same frequency, rate and/or volume or at one or more different frequencies, rates and/or volumes. The repetitive intermittent audible sound could form a bass part of the music.

Preferably the device has one or more speakers associated with the same to allow the audio to be played and/or sounded in a particular locality. For example the one or more speakers can be located on or in the device itself and/or one or more speakers can be located remote from the device and can be communicate with said device via wired and/or wireless means.

Preferably the device is powered by powered means and can include any or any combination of a mains power supply, one or more batteries, rechargeable batteries, solar power and/or the like.

The repetitive intermittent audible sound can be pre-recorded and stored in memory means provided in or associated with the device for playback via the device. Alternatively, the audible sound can be generated live via electronic means provided in or associated with the device.

The device can be provided with micro-processing means for processing, receiving and/or generating, data, signals and/or the like.

Control means can be provided on or associated with the device to allow operational control of the device and/or the like.

The device could be actuated directly via a user and/or following detection of one or more characteristics, such as for example following the detection of smoke, excessive heat, gas and/or the like. Suitable sensing means can be provided on or associated with the device to allow detection of said one or more characteristics.

In one embodiment the device can be actuated indirectly following the actuation of one or more other devices, such as following the actuation of a conventional fire alarm and/or the like. The device can therefore be activated automatically on activation of a conventional fire alarm or once one or more pre-determined conditions relating to the fire alarm are detected.

In one embodiment the signal trigger for actuation of the device is received from an auxiliary output of a conventional fire alarm.

Preferably the repetitive intermittent audio sound is generated via electronic means. The audio can be stored in memory means or can be generated directly by electronic means.

In one embodiment the movement control device is in the form of an evacuation device. Further preferably the evacuation device is for use on a stairwell or staircase of a building, arena, sports ground or structure.

In one embodiment of the present invention the audio of the evacuation device is sounded in addition or at the same time as the sounding of a conventional fire alarm or other alarm system. The rate, frequency and/or volume of the audio sound of the evacuation device is such that it can be clearly distinguished from the audio sound emitted via the conventional alarm and does not interfere with the same. Thus, in one embodiment the present invention is complementary to existing evacuation devices.

In one embodiment the frequency, rate and/or volume of the intermittent audio sound changes over time following initial activation of the sound. For example, the frequency, rate and/or volume of the intermittent audio sound can change automatically after one or more pre-determined time periods and/or a user can initiate the change using adjustment means provided or associated with the device.

The device of the present invention can use intelligent sensing means to allow the same to be adaptable to different detected circumstance and/or conditions. For example, if the device is being used in a “test” mode, such as in a fire drill, the device may emit an audio sound at a frequency or rate that is different to that emitted when a real fire is detected.

In one aspect of the present invention there is provided an evacuation system, said system including at least a first evacuation device in a first locality and at least a second evacuation device provided in a second locality, the intermittent audio sound emitted from said at least first and second evacuation devices guiding the movement of one or more people between said localities, to said localities and/or between said localities.

Preferably the audio emitted from said at least first and second evacuation devices is sounded in substantial synchrony or substantially simultaneously.

According to an aspect of the present invention there is provided an evacuation device, said evacuation device including audio means for emitting audible sound, at least part of said audible sound emitted including an intermittent audible sound, the intermittent audible sound provided at a pre-determined frequency and/or rate sufficient to allow a user hearing the sound to fall into step with the intermittent sound to affect the speed at which said user moves from a first locality to at least a second locality.

According to one aspect of the present invention there is provided a method of using an evacuation device and/or evacuation system.

According to further independent aspects of the present invention there is provided crowd movement control means or movement control means for moving one or more people from a first locality to at least a second locality.

Embodiments of the present invention will now be described in more detail.

Two studies are detailed below to illustrate the success of the present invention.

Study 1

The evacuation device was tested as a movement control means in a stairwell of a Leeds University building, UK to monitor whether the speed at which students exited a lecture theatre could be influenced.

The average rate of footstep of the students was first measured at a particular time of day (noon on a Friday), at a particular stairwell location with a particular group of students, thereby minimizing the variables associated with the test. The students had an average age of 20 years, including both males and females. They were unaware they were taking part in an experiment so as not to influence the speed at which they moved from the lecture theatre. Ethical permission for the experiment was applied for and granted by the Faculty of Biological Sciences Ethical Committee. As video data were also to be collected the students were notified, by posters placed around the building, that at some time in the semester there may be video recording of stairwell movement. The time and day of this video recording was not advertised.

Two sets of stairs in the stairwell were used for the experiment; a short flight of 13 steps (average depth 0.15 m, average width 0.46 m, total distance 6.34 m), followed by a longer flight of 23 steps (average depth 0.15 m, average width 0.46 m, total distance 11 m). Students were timed individually from lifting a leg to start the descent of the steps to placing a foot on the base after the final step of the stairwell. The timing was then calculated as a step rate/minute. The average step rate was calculated for the students without additional sound and used as a guide to determine the presentation rate of the rhythmic beat for testing a repetitive intermittent sound according to the present invention When no sound was emitted from the evacuation device of the present invention, the average rate of footstep for the students was 81.6 steps/minute or 0.71 m/sec. The range of movement speeds to descend the 13 steps was 45-133 steps/minute (mean+/−SEM 9.554+/−0.47 seconds (n=35)).

The experiment was repeated for the same group of students, at the same time of day, on the same day of the week (noon on a Friday), on the same stairwell as the control group. Once again the students were unaware they were taking part in an experiment so as not to influence the speed at which they moved from the lecture theatre. This time a repetitive, “rhythmic”, intermittent audible drum beat was played by the evacuation device at a predominant frequency of 500 Hz, at a rate of 96 beats/minute and at a volume of 60 dBA at a range of 1 metre from the device. The sound continued until the last student had left the stairwell. The range of time for the students to descend the 13 steps was not dissimilar to the control when sounds was not present 57-146 steps/minute (or 5.35-13.78) but the majority of the results were clustered around the mean (as seen by the lower SEM value below).

The means+/−SEM for 13 steps was 8.44+/−0.24 seconds (n=50). This translates to an average rate of footstep recorded for the students as 92.4 steps/minute or 0.81 m/sec. This equated to a 14% increase in stairwell descent time.

An unpaired t-test was performed on the data from the 13 step stairs between the control and the use of the evacuation device. The use of the evacuation device was found to produce a significantly faster rate of movement (p<0.05), thereby indicating that the inclusion of the repetitive intermittent sound at said pre-determined frequency, rate and volume had a significant impact on the movement of the students.

Since the sound used in the above experiment was below ambient sound levels, this indicates that the sound used in the present invention has the potential to have a significant psychoacoustic influence.

Thus, the above experiment shows that the evacuation device of the present invention can influence the speed at which people move from one locality to another locality.

Study 2

The evacuation device was tested as a movement control means on a stairwell at Leeds City Train Station in the UK to monitor whether a repetitive intermittent audio sound could be used to influence the speed of movement of commuters on the said section of platform. In contrast to the university stairwell environment, the train station environment has a greater background noise level and is in a less confined area.

A stairwell between two platforms was chosen as the measurement area for the study. The stairwell was 21.25 m in length and was made up of five sets of stairs, each 2.81 m in length with four landings separating the stair sets, each landing 1.8 m in length.

A control test was undertaken on a Friday between 11.30 am-1 pm, a time period that is not considered to be rush-hour at the train station in question, thereby allowing commuters substantially free, unobstructed movement along the chosen section of platform. The control test was undertaken without a repetitive intermittent audio sound being played. 118 subjects were measured.

A further test was undertaken on a Friday a week later between the same time period as the control test of 11.30 am-1 pm. In this further test a repetitive intermittent audio sound in the form of a drum beat was played at a frequency of 500-600 Hz and 156 beats per minute (bpm) on the stairwell, and played at 65 dB at a distance of 1 m from the microphone. The drum beat was sounded through speakers located on the concourse and was audible but not obtrusive. The background noise level during the test was measured as being 71-80 dB. 139 subjects were measured.

In both tests, the commuters were not aware that they were taking part in a study. The movement data for each commuter included in the study was calculated by counting the number of steps taken for covering the measurement area. The commuters were chosen at random but commuters who were running, listening to electronic devices or who were visibly disabled were not included in the results. The collected data were separated according to gender and approximate age, with age groups split into under 10 years and then 15 year increments thereafter.

Statistical testing using unpaired t-tests were used to compare the control test group to the drumbeat (156 bpm) test group on the stair section of the measurement area.

TABLE 1
Results for Stairs Section of Measurement Area

| | | Control Test | 156 bpm Test | |
|---|---|---|---|---|
| | Age | Walking speed | Walking speed | |
| Gender | Range | (m/s) | (m/s) | P Value |
| Male | 11-25 | 1.136 (+/−0.175) | 1.245 (+/−0.279) | 0.163253 |
| | 26-40 | 1.192 (+/−0.295) | 1.282 (+/−0.220) | 0.065397 |
| | 41-55 | 1.018 (+/−0.201) | 1.072 (+/−0.181) | 0.148639 |
| | 56-70 | 0.964 (+/−0.176) | 1.069 (+/−0.136) | 0.117593 |
| | Total | 1.116 (+/−0.246) | 1.173 (+/−0.230) | 0.046981 |
| Female | 11-25 | 1.015 (+/−0.134) | 1.112 (+/−0.198) | 0.026198 |
| | 26-40 | 0.998 (+/−0.182) | 1.076 (+/−0.173) | 0.138173 |
| | 41-55 | 0.814 (+/−0.126) | 1.056 (+/−0.145) | 0.003893 |
| | 56-70 | 1.003 (+/−0.050) | 0.951 (+/−0.100) | 0.289239 |
| | Total | 0.973 (+/−0.166) | 1.088 (+/−0.182) | 0.000787 |
| Combined | 11-25 | 1.082 (+/−0.816) | 1.144 (+/−0.223) | 0.087894 |
| (Male + | 26-40 | 1.118 (+/−0.273) | 1.244 (+/−0.226) | 0.004703 |
| Female) | 41-55 | 0.967 (+/−0.204) | 1.069 (+/−0.173) | 0.013495 |
| | 56-70 | 0.974 (+/−0.151) | 1.053 (+/−0.135) | 0.118509 |
| | Total | 1.063 (+/−0.230) | 1.146 (+/−0.219) | 0.000840 |

A significant increase (p=0.0008) in walking speed was found for the commuter group hearing a repetitive intermittent audio drumbeat of 156 bpm on the stair section of the measurement area (1.146 m/s+/−0.219 m/s) compared to the walking speed of the commuter group who had no audio drum beat played (1.063 m/s+/−0.230 m/s).

The greatest increase in walking speed when a drum beat was played compared to the control group was found for female commuters, particularly on the stair section of the measurement area.

When age was considered, the greatest increase in walking speed when a drum beat was played compared to the control group was found in the age ranges of 26-40 year olds (p=0.005) and 41-55 year olds (p=0.013).

Thus, the results show that use of a repetitive intermittent audible drum beat played at an audible level can increase the speed of movement of a group of people from a first locality to a second locality, particularly on stairs.

1. A movement control device, said device including audio means for emitting sound audible to a human, wherein at least part of the audible sound emitted includes a repetitive intermittent audible sound provided at such a frequency and/or rate sufficient to allow a person hearing the sound to fall into step with the sound to affect the speed at which the person moves from a first locality to at least a second locality.

2. A movement control device according to claim 1 wherein adjustment means are provided to allow adjustment of any or any combination of the frequency of sound, rate of sound, volume of sound of the repetitive intermittent audible sound and/or the like.

3. A movement control device according to claim 1 wherein the frequency of the repetitive intermittent audible sound is within the range of 200 Hz-4 kHz.

4. A movement control device according to claim 3 wherein the frequency of the repetitive intermittent audible sound is within the range of 450-550 Hz.

5. A movement control device according to claim 3 wherein the frequency of the repetitive intermittent audible sound is approximately 500 Hz.

6. A movement control device according to claim 1 wherein the rate of the repetitive intermittent audible sound is within the range of 40-160 bpm.

7. A movement control device according to claim 6 wherein the rate of the repetitive intermittent audible sound is approximately 96 bpm.

8. A movement control device according to claim 1 wherein the audible sound is played at a volume within the range of 70-85 dB or close to ambient sound levels in the locality of the device.

9. A movement control device according to claim 1 wherein the device includes volume measurement means for measuring the ambient noise level in the locality in which the device is located, said device having means to adjust the volume of the audible sound emitted therefrom to a level substantially equal to or above the measured ambient noise level.

10. A movement control device according to claim 1 wherein the device once activated will play said repetitive intermittent audible sound for the duration of activation of the device.

11. A movement control device according to claim 1 wherein the device includes timing means to allow said repetitive intermitted audible sound to be played for one or more pre-determined time periods.

12. A movement control device according to claim 1 wherein the time period between each audible sound where no sound is emitted from the device is substantially equal in length for the duration of playing of the repetitive intermittent audible sound, is unequal in length, increases or decreases in length over the time of activation of the device.

13. A movement control device according to claim 1 wherein the repetitive intermittent audible sound forms part of a piece of music being played by the device.

14. A movement control device according to claim 1 wherein said device further includes or is associated with any or any combination of power means, speaker means, micro-processing means, memory means or control means.

15. A movement control device according to claim 1 wherein the device is capable of communicating with a conventional fire alarm and activation of said fire alarm results in automatic activation of said movement control device.

16. A movement control device according to claim 1 wherein user actuation means are provided on the device to allow manual activation of the device.

17. A movement control device according to claim 1 in the form of an evacuation device.

18. A movement control device according to claim 1 wherein the frequency and/or rate of the repetitive intermittent audible sound increases or decreases with time following initial activation of the device.

19. A movement control device according to claim 1 wherein the repetitive intermittent audible sound is in the form of a drum beat.

20. A movement control device according to claim 1 wherein sensing means are provided on or associated with the device for sensing any or any combination of smoke, excessive heat or gas.

21. A method of using a movement control device, said device including audio means for emitting sound audible to a human, wherein said method includes the step of emitting a repetitive intermittent audible sound from said device that is provided at such a frequency and/or rate sufficient to allow a person hearing the sound to fall into step with the sound to affect the speed at which the person moves from a first locality to at least a second locality.
